(19) United States
(12) Patent Application Publication
(10) Pub. No.: US 2008/0248431 A1
(43) Pub. Date: Oct. 9, 2008

(54) PATTERN FORMING METHOD USED IN SEMICONDUCTOR DEVICE MANUFACTURING AND METHOD OF MANUFACTURING SEMICONDUCTOR DEVICE

(76) Inventors: Yuriko Seino, Kanagawa-ken (JP); Seiro Myoshi, Kanagawa-ken (JP); Kazutaka Ishigo, Kanagawa-ken (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/944,170

(22) Filed: Nov. 21, 2007

(30) Foreign Application Priority Data
Nov. 24, 2006 (JP) 2006-317522

(51) Int. Cl. G03F 7/20

(52) U.S. Cl. 430/316; 430/323

(57) ABSTRACT

A pattern forming method includes forming a first anti-reflection coating on a substrate, the substrate having an uneven surface; forming a second anti-reflection coating on the first anti-reflection coating, the first anti-reflection coating having an uneven surface, and the second anti-reflection coating planarizing the uneven surface of the first anti-reflection coating; forming an intermediate layer film on the second anti-reflection coating; forming a resist film on the intermediate-layer film; patterning the resist film to form a resist pattern; forming an intermediate-layer pattern by etching the intermediate-layer film using the resist pattern as a mask; and forming an under-layer pattern by etching the first and second anti-reflection coatings using the intermediate-layer pattern as a mask.

### CROSS-REFERENCE TO RELATED APPLICATIONS

This application is based upon and claims the benefit of priority from prior Japanese Patent Application No. 2006-317522, filed Nov. 24, 2006, the entire contents of which are incorporated herein by reference.

### BACKGROUND OF THE INVENTION

1. Field of the Invention

This invention relates to a method of forming a multi-layer resist film on a substrate for manufacturing a semiconductor device and, more particularly, to a method of forming an under-layer film, an intermediate-layer film and a resist film on a processing-object substrate, or a method of forming an under-layer film and a resist film on a processing-object substrate.

2. Description of the Related Art

The finer semiconductor elements have become, the more resist films have been reduced in thickness. However, the reduction in thickness of resist films has caused a problem that the thinner resist films do not retain a sufficient resistance as a resist mask. To address this problem, a multi-layer resist pattern forming method has been employed in recent years. In the multi-layer resist pattern forming method, a film comprising three layers of an under-layer film, an intermediate-layer film and a resist film is formed on a processing-object film which is formed on a silicon substrate, and then a resist pattern is transferred onto the intermediate-layer film, the under-layer film and the processing-object film in this order. Alternatively, in the multi-layer resist pattern forming method, a film comprising two layers of an under-layer film and a resist film is formed on the processing-object film, and then a resist pattern is transferred onto the under-layer film and the processing-object film in this order. (refer to, for example, Japanese Patent Application Laid-open Publication No. 2002-198295).

In order to form the film of three layers, an under-layer film is first formed on a processing-object film. The under-layer film serves as an anti-reflection coating that sufficiently covers the surface unevenness of the processing-object film. Then, an intermediate-layer film is formed thereon, and then a resist film is further formed thereon. The intermediate-layer film is, for example, a spin on glass (SOG) film, and has a certain degree of resistance as a mask.

Thereafter, the resist film is patterned by means of photolithography. The pattern is transferred onto the intermediate-layer film by means of etching using the patterned resist film as a mask. Next, the pattern is further transferred onto the under-layer film by means of etching using the patterned intermediate-layer film as a mask. After that, the processing-object film is finally processed using the under-layer film as a mask.

As the under-layer film, a chemical vapor deposition (CVD) film, although being expensive, has recently been used instead of a coating material such as a spin-coated film. While the film forming temperature of coating films is about 300° C., the CVD film allows the film forming temperature thereof to be increased to 500° C. or more. As a result, the carbon content of the formed film can be increased, resulting in an increase in its resistance as a mask.

Moreover, using a spin-coated film as an under-layer film has another problem. When the inorganic processing-object film is dry-etched with a fluorine-based reaction gas using the under-layer film pattern as a mask, the hydrogen contained in the spin-coated film reacts with the fluorine-based reaction gas during processing. This fluorination reaction reduces the glass transition temperature of the under-layer film. As a result, particularly when the under-layer film has a fine pattern with a line width less than 60 nm, the under-layer film pattern is deformed.

A CVD film is characterized by having a lower hydrogen content after being formed than a spin-coated film. Accordingly, a CVD film is less reactive with a fluorine-based reaction gas. As a result, when a CVD film is used as an under-layer film, the under-layer film is hardly deformed (refer to, for example, J. Abe, et al.: Proc. of Symp. Dry Process (2005) 11).

However, a CVD film is a film conformally formed in a uniform thickness. Accordingly, when formed on a processing-object film having a concavo-convex surface, a CVD film has a disadvantage of having poorer local flatness than a spin-coated film. Accordingly, when an intermediate-layer film and a resist film are formed on a CVD film by means of a spin coating method, the intermediate-layer film and the resist film become locally uneven in thickness on the uneven portion of the CVD film.

Therefore, in carrying out reactive ion etching (RIE) using the resist pattern as a mask, etching time varies locally in accordance with the film thickness. In particular, when a SOG film having a high selectivity is used as the intermediate-layer film, the variation in the etching time causes the following problem on a processed surface. When the etching is carried out in accordance with portions having a small film thickness, portions having a large film thickness are under-etched and the SOG film is left on these thicker portions. On the contrary, when the etching is carried out in accordance with portions having a large film thickness, portions having a small film thickness are over-etched and the resist film becomes insufficient in thickness on these thinner portions.

In lithography, the uneven thickness of the intermediate-layer film and the resist film formed on the uneven portion of the CVD under-layer film causes variation of a critical dimension (CD), a reflection coefficient and a shape in performing an exposure so that lithography performance is deteriorated.

### BRIEF SUMMARY OF THE INVENTION

In accordance with an aspect of the invention, there is provided a pattern forming method, comprising: forming a first anti-reflection coating on a substrate, the substrate having an uneven surface; forming a second anti-reflection coating on the first anti-reflection coating, the first anti-reflection coating having an uneven surface, and the second anti-reflection coating planarizing the uneven surface of the first anti-reflection coating; forming an intermediate-layer film on the second anti-reflection coating; forming a resist film on the intermediate-layer film; patterning the resist film to form a resist pattern; forming an intermediate-layer pattern by etching the intermediate-layer film using the resist pattern as a mask; and forming an under-layer pattern by etching the first and second anti-reflection coating using the intermediate-layer pattern as a mask.

In accordance with another aspect of the invention there is provided a method of manufacturing a semiconductor device, comprising: forming a first anti-reflection coating on a processing-object substrate, the substrate having an uneven surface; forming a second anti-reflection coating on the first anti-reflection coating, the first anti-reflection coating having an uneven surface, and the second anti-reflection coating planarizing the uneven surface of the first anti-reflection coating; forming a SOG oxide film on the second anti-reflection coating; forming a resist film on the SOG oxide film; patterning the resist film to form a resist pattern by pattern exposure; forming an intermediate-layer pattern by etching the SOG film using the resist pattern as a mask; forming an under-layer pattern by etching the first and second anti-reflection coatings using the intermediate-layer pattern as a mask; and forming a processing-object pattern by etching the processing-object substrate using the under-layer pattern as a mask.

In accordance with another aspect of the invention there is provided a method of manufacturing semiconductor device, comprising: forming a first anti-reflection coating on a processing-object substrate, the substrate having an uneven surface; forming a second anti-reflection coating as an organic film on the first anti-reflection coating, the first anti-reflection coating having an uneven surface, and the second anti-reflection coating planarizing the uneven surface of the first anti-reflection coating; forming a resist film on the second anti-reflection coating; patterning the resist film to form a resist pattern; forming an under-layer pattern by etching the first and second anti-reflection coatings using the resist pattern as a mask; and forming a processing-object pattern by etching the processing-object substrate using the under-layer pattern as a mask.

### BRIEF DESCRIPTION OF THE SEVERAL VIEWS OF THE DRAWING

FIG. 1 is a sectional view explaining one manufacturing process using a method of forming pattern according to first and second embodiments of the invention;

FIG. 2 is a sectional view explaining one manufacturing process using the method of forming a pattern according to the first and second embodiments of the invention, following the manufacturing process shown in FIG. 1

FIG. 3 is a sectional view explaining one manufacturing process using the method of forming a pattern according to the first and second embodiments of the invention, following the manufacturing process shown in FIG. 2;

FIG. 4 is a sectional view explaining one manufacturing process using the method of forming a pattern according to the first and second embodiments of the invention, following the manufacturing process shown in FIG. 3;

FIG. 5 is a sectional view explaining one manufacturing process using the method of forming a pattern according to the first and second embodiments of the invention, following the manufacturing process shown in FIG. 4

FIG. 6 is a sectional view explaining one manufacturing process using the method of forming a pattern according to the first and second embodiments of the invention, following the manufacturing process shown in FIG. 5;

FIG. 7 is a sectional view explaining one manufacturing process using the method of forming a pattern according to the first and second embodiments of the invention, following the manufacturing process shown in FIG. 6;

FIG. 8 is a sectional view explaining one manufacturing process using the method of forming a pattern according to the first and second embodiments of the invention, following the manufacturing process shown in FIG. 7;

FIG. 9 is a sectional view explaining one manufacturing process using a method of forming a pattern according to a conventional art;

FIG. 10 is a sectional view explaining one manufacturing process using the method of forming a pattern according to the conventional art, following the manufacturing process shown in FIG. 9;

FIG. 11 is a sectional view explaining one manufacturing process using the method of forming a pattern according to the conventional art, following the manufacturing process shown in FIG. 10;

FIG. 12 is a sectional view explaining one manufacturing process using the method of forming a pattern according to the conventional art, following the manufacturing process shown in FIG. 9;

FIG. 13 is a sectional view explaining one manufacturing process using the method of forming a pattern according to the conventional art, following the manufacturing process shown in FIG. 12;

FIG. 14 is a sectional view explaining one manufacturing process using a method of forming a pattern according to a second embodiment of the invention;

FIG. 15 is a sectional view explaining one manufacturing process using the method of forming a pattern according to the second embodiment of the invention, following the manufacturing process shown in FIG. 14;

FIG. 16 is a sectional view explaining one manufacturing process using the method of forming a pattern according to the second embodiment of the invention, following the manufacturing process shown in FIG. 15;

FIG. 17 is a sectional view explaining one manufacturing process using a method of forming a pattern according to a third embodiment of the invention;

FIG. 18 is a sectional view explaining one manufacturing process using the method of forming a pattern according to the third embodiment of the invention, following the manufacturing process shown in FIG. 17;

FIG. 19 is a sectional view explaining one manufacturing process using the method of forming a pattern according to the third embodiment of the invention, following the manufacturing process shown in FIG. 18;

FIG. 20 is a sectional view explaining one manufacturing process using the method of forming a pattern according to the third embodiment of the invention, following the manufacturing process shown in FIG. 19;

FIG. 21 is a sectional view explaining one manufacturing process using the method of forming a pattern according to the third embodiment of the invention, following the manufacturing process shown in FIG. 20;

FIG. 22 is a sectional view explaining one manufacturing process using the method of forming a pattern according to the third embodiment of the invention, following the manufacturing process shown in FIG. 21;

FIG. 23 is a graph explaining a relationship between thickness of a spin-coated under-layer film and contrast intensity of alignment light (arbitrary unit), in the case of forming an under-layer film using the method of forming a pattern according to the third embodiment of the invention; and

FIG. 24 is a sectional view explaining a structure of a conventional semiconductor device, in which an under-layer film is formed as a single layer, having a pattern for alignment; and

FIG. 25 is a graph explaining a relationship between thickness of an under-layer film and contrast intensity of alignment light (arbitrary unit), in the case of an under-layer film formed as a single layer.

### DETAILED DESCRIPTION OF THE INVENTION

### First Embodiment

FIGS. 1 to 8 show cross-sectional views of manufacturing process steps of a pattern forming method according to a first embodiment of the present invention. In the present embodiment, the unevenness of a CVD under-layer film formed conformally (in a uniform thickness) is planarized by forming a spin-coated under-layer film on the CVD under-layer film, in a method of forming a multi-layer resist pattern comprised of three layers made of an under-layer film, an intermediate-layer film, and a resist film.

As shown in FIG. 1, a processing-object film 2 having an uneven surface, e.g., including steps as shown in FIG. 1, or other surface roughness, is formed on a silicon substrate 1. The material of the processing-object film 2 may be any of a semiconductor, metal, and an insulation film, and is not specifically limited.

As shown in FIG. 2, a CVD under-layer film 3 is first formed on the processing-object film 2 by a CVD method. The CVD under-layer film 3 is a CVD carbon film containing carbon as a major component, and is a first anti-reflection coating to function as an anti-reflection coating to exposure light in carrying out resist exposure. The CVD under-layer film 3 is formed conformally on a substrate, and has an uneven surface formed due to the unevenness of the processing-object film 2. Alternatively, a sputtered carbon film may here be formed as the under-layer film 3 by using a sputtering forming method as a method of forming a conformal film.

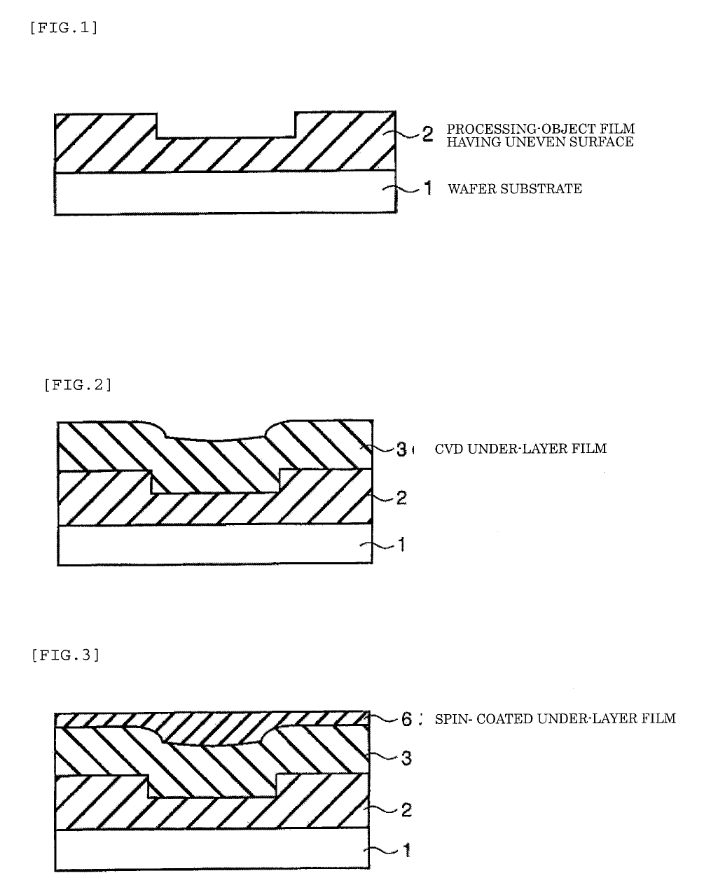

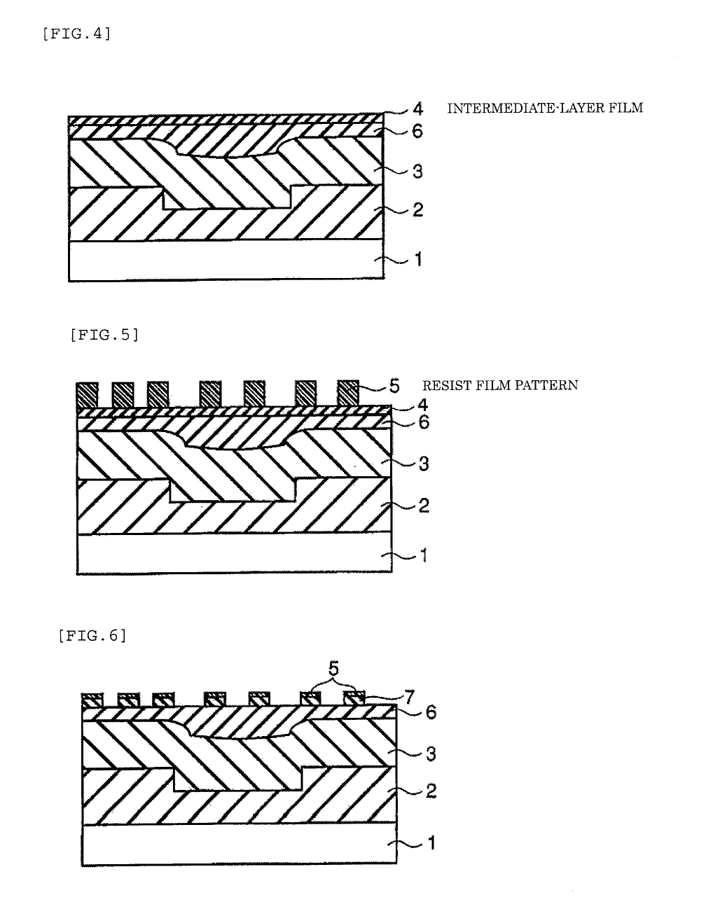

Subsequently, as shown in FIG. 3, an under-layer film solution is applied on the CVD under-layer film 3 by a spin coating method (rotary coating method). The coating film is heated to form a spin-coated under-layer film 6, thereby planarizing the unevenness of the CVD under-layer film 3. The under-layer film solution is prepared by dissolving a resin comprised of carbon (C), hydrogen (H), oxygen (O) in an organic solvent, and the spin-coated under-layer film is an organic film. The spin-coated under-layer film 6 is a second anti-reflection coating to function as an anti-reflection coating to the exposure light in carrying out resist exposure. The spin coating method is simple and easy in the processes thereof, and at low cost. However, an alternative method which allows the unevenness of the CVD under-layer film 3 to be planarized, such as a flow casting applying method or a roll applying method, may be used.

As shown in FIG. 4, an SOG intermediate-layer film 4 which is a SiO₂ film is then formed on the spin-coated under-layer film 6. The unevenness of the CVD under-layer film 3 has been planarized with the spin-coated under-layer film 6. Therefore, the SOG intermediate-layer film 4 can be formed flatly and with a uniform thickness.

As shown in FIG. 5, a resist pattern 5 is further formed on the SOG intermediate-layer film 4. Specifically, a resist film 5 is formed and exposed to light. Then the resist film 5 is subjected to an alkali development process so that the resist pattern 5 can be formed. In the present embodiment, the SOG intermediate-layer film 4 and the resist film 5 have no unevenness in thickness due to the uneven portions of the CVD under-layer film 3. By assuring a sufficient total thickness of the CVD under-layer film 3 and the spin-coated under-layer film 6, deterioration of lithography performance that would result from variation of a CD dimension, a reflection coefficient, and a shape in carrying out exposure, can be avoided.

As shown in FIG. 6, the SOG intermediate-layer film 4 is then etched by, for example, a dry etching method using the resist pattern 5 as a mask to form an intermediate-layer film pattern 7. In the present embodiment, a problem does not arise that, by carrying out etching in accordance with portions having a small film thickness, portions having a large film thickness are under-etched and that the SOG intermediate-layer film 4 is left on these thicker portions, because the SOG intermediate-layer film 4 has a uniform thickness. A problem also does not arise that, by carrying out etching to suit a portion having a large film thickness, portions having a small film thickness are over-etched and that the resist pattern 5 becomes insufficient in film thickness on these thinner portions.

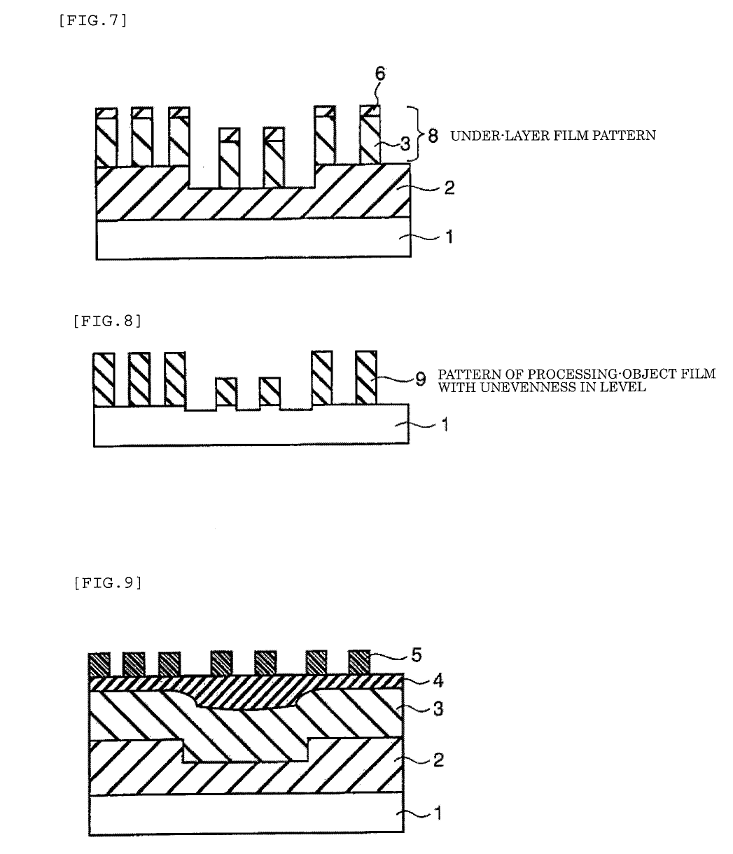

As shown in FIG. 7, the spin-coated under-layer film 6 and the CVD under-layer film 3 are then etched by, for example, a dry etching method using the intermediate-layer film pattern 7 as a mask to form an under-layer pattern 8. As shown in FIG. 8, a pattern 9 of the processing-object film is finally formed by carrying out dry-etching with, for example, a fluorine-based reaction gas using, as a mask, the under-layer film pattern 8 comprised of the spin-coated under-layer film 6 and the CVD under-layer film 3 which have been etched, thereby being able to produce a semiconductor device. The pattern 9 of the processing-object film is a pattern having an unevenness in level formed due to the unevenness of the processing-object film 2 in FIG. 1.

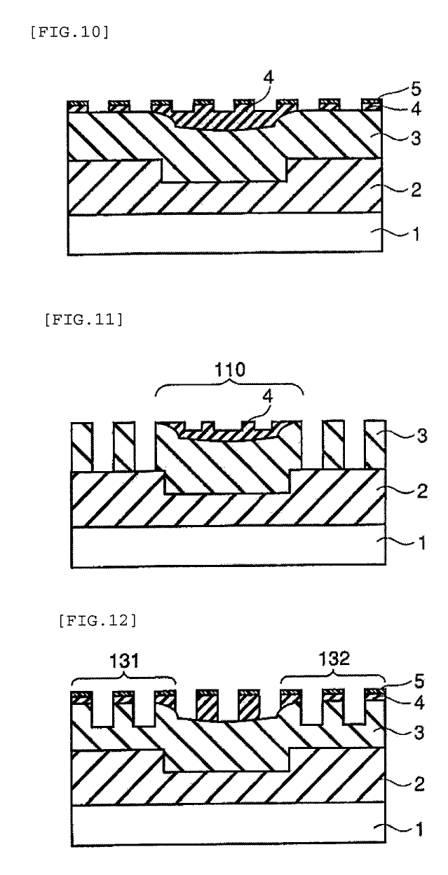

Here, for comparison, a case is assumed in which the SOG intermediate-layer film 4 which is a SiO₂ film is formed, as shown in FIG. 9, without forming the spin-coated under-layer film 6 as shown in FIG. 3 after the CVD under-layer film 3 is formed in FIG. 2.

In this case, the SOG intermediate-layer film 4 has an uneven thickness due to the uneven portion of the CVD film. Therefore, deterioration of lithography performance that would result from variation of a CD dimension, a reflection coefficient, and a shape in exposing the resist pattern 5 to light, can be avoided.

As shown in FIG. 10, when carrying out etching in accordance with portions having a small film thickness of the SOG intermediate-layer film 4, portions having a large film thickness are under-etched and the SOG intermediate-layer film 4 is left on these thicker portions. Therefore, as shown in FIG. 11, when processing is further advanced, the CVD under-layer film 3 and the processing-object film 2 cannot be processed in portion 110 in which the SOG intermediate-layer film 4 is left.

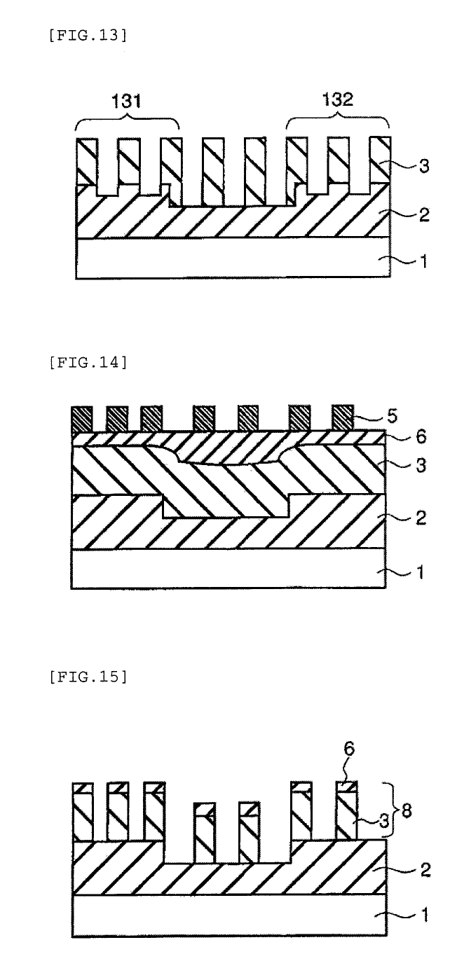

Alternatively, as shown in FIG. 12, when carrying out etching in accordance with portions having a large film thickness of the SOG intermediate-layer film 4, portions having a small film thickness are over-etched. Accordingly, in some cases, etching is carried out through the SOG intermediate-layer film 4 and into the CVD under-layer film 3 in portions having a small film thickness. In this case, as shown in FIG. 12, when an etching rate of the CVD under-layer film 3 is high, portions 131 and 132 in which the intermediate-layer film 4 has a small thickness are more deeply etched. Therefore, when processing is further advanced, the CVD under-layer film 3 and the processing-object film 2 are etched more deeply than necessary in the portions 131 and 132 in which the intermediate-layer film 4 has a small film thickness as shown in FIG. 13.

However, as described above, in the pattern forming method according to the present embodiment, it is possible to etch the SOG intermediate-layer film 4 which is formed on the under-layer film and which is difficult to be etched, to have a uniform rather than a varied thickness, by planarizing the unevenness of the CVD under-layer film 3 with the spin-coated under-layer film 6 formed thereon. Accordingly, the method according to the present embodiment can overcome problems that the residual of the SOG intermediate-layer film 4 is left after etching, and that the insufficient resistance of the mask is encountered in the process because of differences in etching time due to the unevenness in film thickness of the SOG intermediate-layer film 4, thereby improving the etching characteristics. Moreover, the method according to the present embodiment can also overcome the above-noted problem that would result from variation of a CD dimension, a reflection coefficient, and a shape in carrying out exposure. Therefore, lithography characteristics are also improved.

In addition, a CVD carbon film used as the CVD under-layer film 3 is generally formed at a high temperature, and therefore has higher carbon content than the spin-coated under-layer film 6 which is an organic film, thereby having a high resistance as a mask. Furthermore, the CVD carbon film has a lower hydrogen content than the spin-coated under-layer film (organic film) because it is formed at a high temperature. Accordingly, a problem can be avoided that the hydrogen in the spin-coated film reacts with the fluorine-based reaction gas during the process in which the processing-object film under the under-layer film is dry-etched with, for example, a fluorine-based reaction gas, with the undesirable result that the under-layer film pattern is deformed and bent.

### Second Embodiment

FIGS. 14 to 16 show cross-sectional views of manufacturing processes of a pattern forming method according to a second embodiment of the present invention. In the present embodiment, the unevenness of the CVD under-layer film is planarized by forming a spin-coated under-layer film on a CVD under-layer film conformally formed in a method of forming a multi-layer resist pattern comprised of two layers made of an under-layer film and a resist film.

In the present embodiment, the processes shown in FIGS. 1 to 3 are the same as in the first embodiment.

In the present embodiment, the intermediate-layer film is not formed after FIG. 3. As shown in FIG. 14, the resist pattern 5 is formed on the spin-coated under-layer film. Specifically, the resist film 5 is formed and exposed to light. Then the resist film 5 is subjected to an alkali development process so that the resist pattern 5 can be formed. In the present embodiment, the resist film 5 has no unevenness in thickness due to the uneven portions of the CVD under-layer film 3. By assuring a sufficient total thickness of the CVD under-layer film 3 and the spin-coated under-layer film 6, deterioration of lithography performance that would result from variation of a CD dimension, a reflection coefficient, and a shape in carrying out exposure, can be avoided.

As shown in FIG. 15, the spin-coated under-layer film 6 and the CVD under-layer film 3 are then etched by, for example, a dry etching method using the resist pattern 5 as a mask to form an under-layer film pattern 8. In the present embodiment, the SOG intermediate-layer film is not formed. Therefore, problems of under-etching and over-etching do not arise.

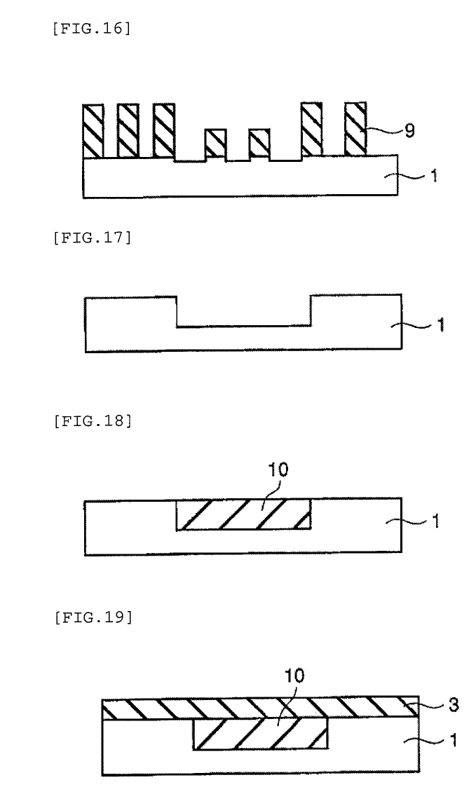

As shown in FIG. 16, the pattern 9 of the processing-object film is finally formed by carrying out dry-etching with, for example, a fluorine-based reaction gas, as a mask, the under-layer pattern 8 comprised of the spin-coated under-layer film 6 and the CVD under-layer film 3 which have been etched. The pattern 9 of the processing-object film is a pattern having an unevenness in level formed due to the unevenness of the processing-object film 2 in FIG. 1.

In the pattern forming method according to the present embodiment, it is possible to form the flat resist pattern 5 on the spin-coated under-layer film 6 by planarizing the unevenness of the CVD under-layer film 3 with the spin-coated under-layer film 6 formed thereon. Moreover, the method according to the present embodiment can also overcome the above-noted problem that would result from variation of a CD dimension, a reflection coefficient, and a shape in carrying out exposure, thereby improving lithography characteristics.

In addition, as in the first embodiment, the CVD under-layer film 3 is made of a CVD carbon film so that it has a high resistance as a mask. As a result, a problem can be avoided that the under-layer film pattern is deformed and bent during etching of the processing-object film.

### Third Embodiment

FIGS. 17 to 22 show cross-sectional views of each manufacturing process of a pattern forming method related to a third embodiment of the present invention. In the present embodiment, a pattern forming method is described in which a contrast intensity of alignment light is assured by forming the CVD under-layer film and the spin-coated under-layer film on the processing-object film on which a pattern for alignment is formed while the thicknesses of these films are adjusted.

As shown in FIG. 17, the silicon substrate 1 as a processing-object substrate has an uneven surface including a ditch. For example, a silicon oxide film 10 which is formed by the CVD method and has a thickness of 250 nm is first buried in the ditch to be a mark for alignment, as shown in FIG. 18. Here, it is assumed that the silicon substrate 1 has other uneven surfaces, such as ditches, which are not shown in FIG. 17 in addition to the above-described ditch.

As shown in FIG. 19, the CVD under-layer film 3 is then formed on the silicon substrate 1 and the silicon oxide film 10 by the CVD method. The CVD under-layer film 3 is a CVD carbon film containing carbon as a main component, and is the first anti-reflection coating which functions as an anti-reflection coating to exposure light in carrying out resist exposure. Alternatively, a sputtered carbon film may be formed as an under-layer film by using the sputtering forming method as a film forming method.

As shown in FIG. 20, an under-layer film solution is then applied on the CVD under-layer film 3 by a spin coating method (rotary coating method). The coating film is thereafter heated to form the spin-coated under-layer film 6. Here, the under-layer film solution is prepared by dissolving a resin comprised of C, H, and O in an organic solvent. The spin-coated under-layer film 6 is an organic film. The spin-coated under-layer film 6 is the second anti-reflection coating to function as an anti-reflection coating to exposure light in carrying out resist exposure. Here, another method such as a flow casting applying method or a roll applying method may be used to form a film.

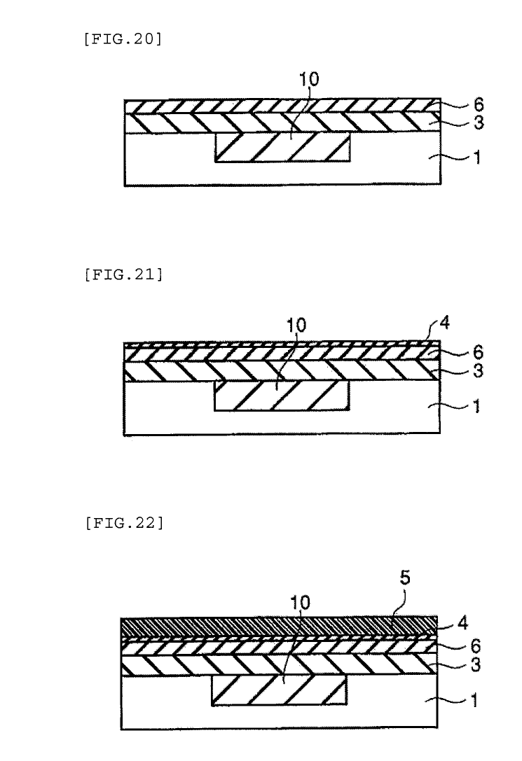

As shown in FIG. 21, the SOG intermediate-layer film 4 which is a SiO₂ film is further formed on the spin-coated under-layer film 6. Although the uneven surface of the ditch of the silicon substrate 1 is not shown in FIG. 17, the uneven surface of the ditch is in a state similar to the uneven surface shown in FIGS. 1 to 4 of the first embodiment.

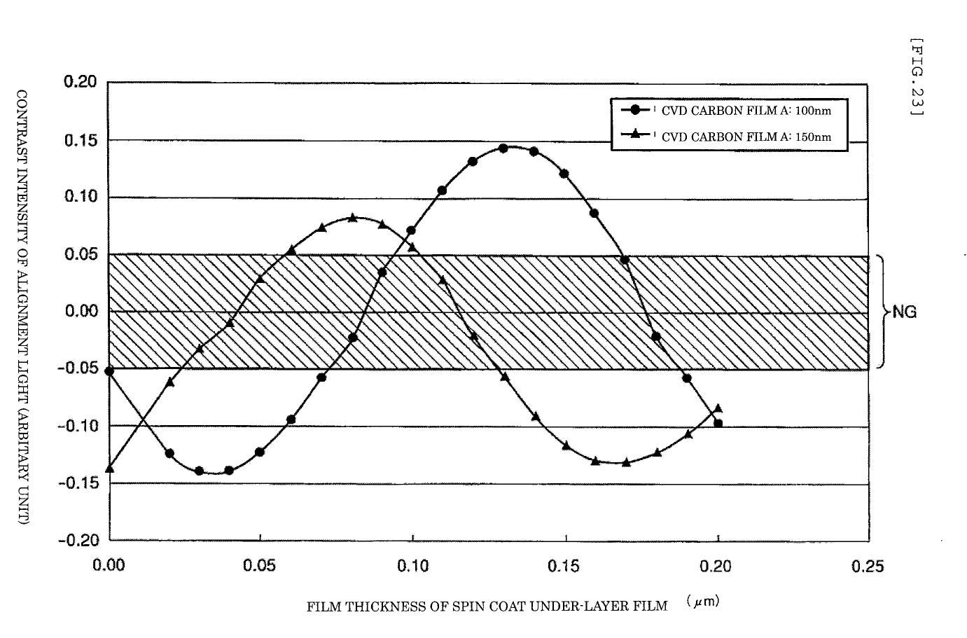

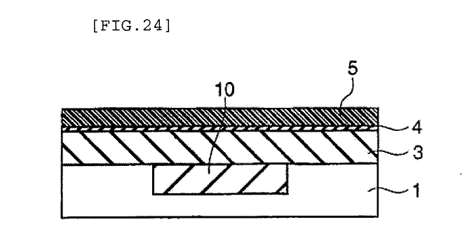

As shown in FIG. 22, a resist film 5 is finally formed. After that, a pattern can be formed in the processing-object substrate to produce a semiconductor device base on the above described embodiment.

In the present embodiment, the spin-coated under-layer film 6 has a smaller absorption coefficient to alignment light than the CVD under-layer film 3, and the CVD under-layer film 3 is opaque to alignment light for exposure (for example, wavelength=633 nm). And the spin-coated under-layer film 6 is laminated on the CVD under-layer film 3. In the processes of forming these under-layer films, the thickness of the CVD under-layer film 3 and the thickness of spin-coated under-layer film 6 are adjusted to increase the intensity of the alignment signal for exposure, thereby making it easier to assure the contrast of the alignment light from the viewpoint of alignment and processing.

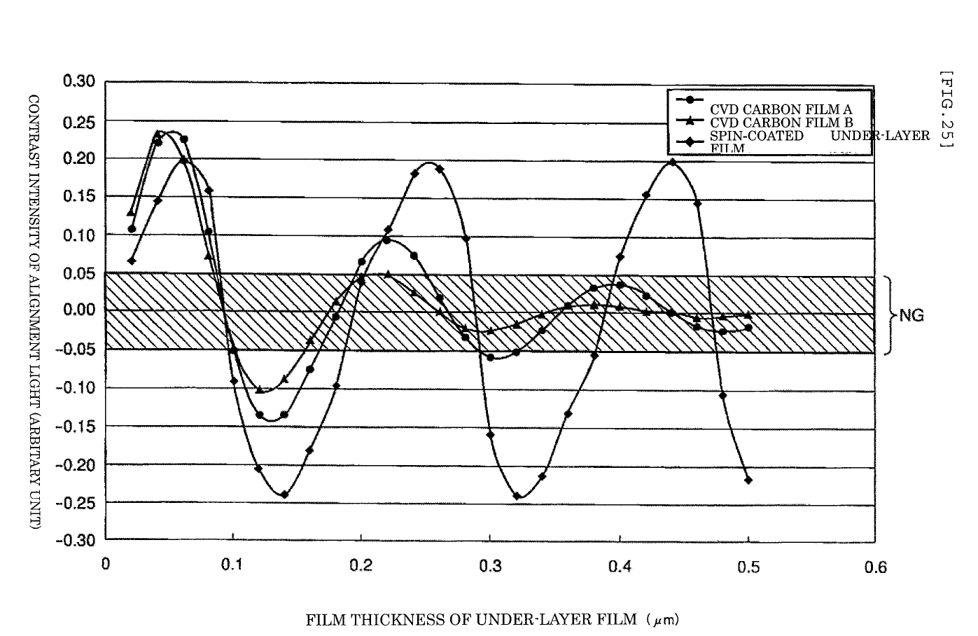

As in the present embodiment, when the spin-coated under-layer film 6 is formed on the CVD under-layer film 3 having a particular thickness, the contrast intensity of the alignment light (arbitrary unit) is varied corresponding to the film thickness of the spin-coated under-layer film 6, as shown in FIG. 23. FIG. 23 is a graph that shows a case in which the spin-coated under-layer film 6 is formed on a CVD carbon film A formed at a particular temperature and for two different kinds of thicknesses of 100 nm and 150 nm.

In FIG. 23, in the case in which the contrast intensity of the alignment light is considered to be insufficient between +0.05 and −0.05, it becomes possible to assure sufficient alignment signal intensity by laminating the spin-coated under-layer film 6 having a thickness of 200 nm on the CVD carbon film A having a thickness of 150 nm, for example.

Here, for comparison, FIG. 25 shows how the contrast intensity of the alignment light (arbitrary unit) varies with the variation of the thickness of the under-layer film in the structure shown in FIG. 24, i.e. a structure in which the under-layer film is a single layer of the CVD carbon film 3 only, or in a structure in which the CVD carbon film 3 in FIG. 24 is replaced with the spin-coated under-layer film 6.

As seen from FIG. 25, the CVD carbon film 3 has so large an absorption coefficient k to the alignment light in carrying out exposure as to be opaque, and accordingly has a disadvantage that, when the thickness thereof is increased, the alignment signal intensity decreases, resulting in the difficulty to assure a contrast. At a film thickness of, for example, 350 nm, the contrast intensity is between +0.05 and −0.05. As a result, the mark for alignment cannot be seen. In general, a CVD carbon film 3 is more opaque than a spin-coated under-layer film 6. The CVD carbon film 3 formed at a higher temperature tends to have higher absorption coefficient k to the alignment light. The CVD carbon film B is formed at a higher temperature than the CVD carbon film A. Accordingly, it can here be seen from FIG. 25 that the CVD carbon film B tends to correspondingly have a higher absorption coefficient.

On the other hand, the spin-coated under-layer film 6 has a small absorption coefficient to the alignment light, and accordingly allows the alignment signal intensity to be periodically varied rather than to decrease with the increase in the thickness thereof. Therefore it becomes possible to assure sufficient alignment signal intensity by adjusting the film thickness.

From the viewpoint of processing properties, a CVD carbon film 3 has a high resistance as a mask, and the under-layer film pattern made of a CVD carbon film does not have a disadvantage of being deformed and bent during etching of the processing-object film.

Accordingly, it becomes possible to assure the sufficient contrast of the alignment light while meeting the conditions required from the viewpoint of processing, such as a sufficient resistance as a mask, and while maintaining the thickness necessary for etching the processing-object film, by laminating the CVD under-layer film 3 and the spin-coated under-layer film 6 and by adjusting the thickness of both films as shown in the present embodiment.

When the film thickness of the CVD under-layer film 3 required from the viewpoint of processing is, for example, 300 nm, the absorption coefficient k of the spin-coated under-layer film 6 is desirably 0.2 or less in order to assure the sufficient contrast of the alignment light.

When the spin-coated under-layer film 6 is controlled and formed so as to have a film thickness which allows the alignment signal intensity (absolute value) to be at the maximum value when the film thickness is varied in FIG. 23, it is further possible to stabilize the contrast intensity of the alignment light against the variation of the film thickness.

The present invention is not limited to the embodiments, and allows various modifications in an implementation stage within a scope without departing from the gist of the invention. The embodiments include various steps of the inventions. Various inventions can be extracted by suitably combining a plurality of disclosed construction requirements. For example, even if several construction requirements are eliminated from all the construction requirements shown in the embodiments, problems described in the section of “Problems to be Solved by the Invention” can be solved and the advantages described in the section of “Advantages of the Invention” are obtained, the construction from which the construction requirements are eliminated can be extracted as an invention.

What is claimed is:

1. A pattern forming method, comprising:
forming a first anti-reflection coating on a substrate, the substrate having an uneven surface;
forming a second anti-reflection coating on the first anti-reflection coating, the first anti-reflection coating having an uneven surface, and the second anti-reflection coating planarizing the uneven surface of the first anti-reflection coating;
forming an intermediate-layer film on the second anti-reflection coating;
forming a resist film on the intermediate-layer film;
patterning the resist film to form a resist pattern;
forming an intermediate-layer pattern by etching the intermediate-layer film using the resist pattern as a mask; and
forming an under-layer pattern by etching the first and second anti-reflection coatings using the intermediate-layer pattern as a mask.

2. The pattern forming method according to claim 1, wherein forming the first anti-reflection coating includes forming the first anti-reflection coating by CVD or sputtering.

3. The pattern forming method according to claim 2, wherein forming the first anti-reflection coating includes forming the first anti-reflection coating as a carbon film.

4. The pattern forming method according to claim 1, wherein forming the second anti-reflection coating includes forming the second anti-reflection coating as an organic film.

5. A method of manufacturing a semiconductor device, comprising:
forming a first anti-reflection coating on a processing-object substrate, the substrate having an uneven surface;
forming a second anti-reflection coating on the first anti-reflection coating, the first anti-reflection coating having an uneven surface, and the second anti-reflection coating planarizing the uneven surface of the first anti-reflection coating;
forming a SOG oxide film on the second anti-reflection coating;
forming a resist film on the SOG oxide film;
patterning the resist film to form a resist pattern by pattern exposure;
forming an intermediate-layer pattern by etching the SOG film using the resist pattern as a mask;
forming an under-layer pattern by etching the first and second anti-reflection coatings using the intermediate-layer pattern as a mask; and
forming a processing-object pattern by etching the processing-object substrate using the under-layer pattern as a mask.

6. The method of manufacturing semiconductor device according to claim 5, wherein forming the first anti-reflection coating includes forming the first anti-reflection coating is formed by CVD or sputtering.

7. The method of manufacturing semiconductor device according to claim 6, wherein a content of carbon contained in the first anti-reflection coating is higher than a content of carbon contained in the second anti-reflection coating.

8. The method of manufacturing semiconductor device according to claim 6, wherein forming the first anti-reflection film includes forming the first anti-reflection coating as a carbon film.

9. The method of manufacturing semiconductor device according to claim 5, wherein a content of hydrogen contained in the first anti-reflection coating is lower than a content of hydrogen contained in the second anti-reflection coating.

10. The method of manufacturing semiconductor device according to claim 5, wherein forming the second anti-reflection film includes forming the second anti-reflection coating as an organic film.

11. The method of manufacturing semiconductor device according to claim 5, further including forming an alignment mark on a surface of the processing-object substrate.

12. The method of manufacturing semiconductor device according to claim 11, wherein an absorption coefficient of the first anti-reflection coating for the alignment light is larger than that of the second anti-reflection coating.

13. A method of manufacturing semiconductor device, comprising:
forming a first anti-reflection coating on a processing-object substrate, the substrate having an uneven surface;
forming a second anti-reflection coating as an organic film on the first anti-reflection coating, the first anti-reflection coating having an uneven surface, and the second anti-reflection coating planarizing the uneven surface of the first anti-reflection coating;
forming a resist film on the second anti-reflection coating;
patterning the resist film to form a resist pattern;
forming an under-layer pattern by etching the first and second anti-reflection coatings using the resist pattern as a mask; and
forming a processing-object pattern by etching the processing-object substrate using the under-layer pattern as a mask.

14. The method of manufacturing semiconductor device according to claim 13, wherein forming the first anti-reflection coating includes forming the first anti-reflection coating by CVD or sputtering.

15. The method of manufacturing semiconductor device according to claim 14, wherein a content of carbon contained in the first anti-reflection coating is higher than a content of carbon contained in the second anti-reflection coating.

16. The method of manufacturing semiconductor device according to claim 15, wherein forming the first anti-reflection coating includes forming the first anti-reflection coating as a carbon film.

17. The method of manufacturing semiconductor device according to claim 13, wherein a content of hydrogen contained in the first anti-reflection coating is lower than a content of hydrogen contained in the second anti-reflection coating.

18. The method of manufacturing semiconductor device according to claim 13, wherein the second anti-reflection coating is formed by using one method selected from a spin coating method, a solution casting method, and a roll casting method.

19. The method of manufacturing semiconductor device according to claim 13, further including forming an alignment mark on a surface of the processing-object substrate.

20. The method of manufacturing semiconductor device according to claim 19, wherein an absorption coefficient of the first anti-reflection coating for the alignment light is larger than that of the second anti-reflection coating.
